(19) United States
(12) Patent Application Publication
(10) Pub. No.: US 2026/0319379 A1
(43) Pub. Date: Oct. 15, 2026

(54) CONTROL METHOD AND NON-TRANSITORY COMPUTER-READABLE STORAGE MEDIUM STORING A PROGRAM FOR EXPOSURE APPARATUS

(71) Applicant: CANON KABUSHIKI KAISHA, Tokyo (JP)

(72) Inventors: Jun MOIZUMI, Tochigi (JP); Ayane HIROTA, Tochigi (JP)

(21) Appl. No.: 19/634,386

(22) Filed: Mar. 31, 2026

(30) Foreign Application Priority Data
Apr. 15, 2025 (JP) 2025-067037

(51) Int. Cl. G03F 7/00

(52) U.S. Cl. CPC G03F 7/70525; G03F 7/70266; G03F 7/70504; G03F 7/706

(57) ABSTRACT

Control method of exposure apparatus configured to expose substrate by projecting pattern of original onto substrate through projection optical system under set illumination condition is provided. Method includes acquiring first light intensity distribution formed on pupil surface of projection optical system when original arranged on object surface is illuminated under illumination condition, and acquiring second light intensity distribution formed when object surface is illuminated under illumination condition without original. Method further includes acquiring first and second variation information indicating variations of optical characteristic of projection optical system affecting imaging of patterns extending in different directions. Control data is generated by weighting variations based on first and second light intensity distributions, and exposure of plurality of substrates is performed based on control data.

### BACKGROUND

### Field of the Technology

The present disclosure relates to a control of an exposure apparatus.

### Description of the Related Art

In a semiconductor process, a substrate is sometimes exposed using a reticle (original) in which a pattern extending in one direction is more dominant than a pattern extending in another direction. Since light with which the reticle is irradiated generates many diffracted beams in one direction, a non-rotation symmetric heat distribution is formed in a projection optical system, and a non-rotation symmetric exposure aberration (to be referred to as an exposure astigmatism hereinafter) is generated.

An exposure astigmatism is represented by the difference between FocusH that exerts influence on imaging of a pattern extending in the horizontal direction (for example, the X-axis direction) on a reticle and FocusV that exerts influence on imaging of a pattern extending in the vertical direction (for example, the Y-axis direction) on the reticle. For example, if a substrate is exposed using a reticle on which a pattern extending in the vertical direction is dominantly arranged, a non-rotation symmetric heat distribution is generated in the projection optical system. As a result, the FocusV generation amount is large, and the FocusH generation amount is small. However, to correct both FocusV and FocusH, a dedicated configuration needs to be added to the projection optical system, resulting in high cost. It is advantageous to provide a method of correcting the average of FocusH and FocusV using an existing correction mechanism (for example, a mechanism that drives a wafer stage in the Z-axis direction).

There is proposed a method of acquiring the pattern of a reticle in advance, calculating the generation direction of diffracted light from the pattern, and also predicting an exposure aberration caused by this (Japanese Patent Laid-Open No. 2019-070812). In this method, however, the diffracted beam generation direction and the exposure aberration caused by this are obtained by calculation, and the result may be different from the actual state. There is also proposed measuring diffracted light, and predicting an exposure aberration using a pupil aberration map obtained in advance (Japanese Patent Laid-Open No 2009-218366). The generated aberration can correctly be obtained by this method, but if an exposure astigmatism is generated, as described above, a hardware configuration for correcting this is needed.

### SUMMARY

The present disclosure provides a technique advantageous in easily reducing a correction residue of an exposure aberration.

One of aspects of the present disclosure provides a control method of an exposure apparatus configured to expose a substrate by projecting, by a projection optical system, a pattern of an original to the substrate under a set illumination condition, comprising: a first acquisition step of acquiring a first light intensity distribution formed on a pupil surface of the projection optical system when the original is arranged on an object surface of the projection optical system and the original is illuminated under the illumination condition and a second light intensity distribution formed on the pupil surface when the object surface is illuminated under the illumination condition without arranging the original on the object surface; a second acquisition step of acquiring first variation information indicating a first variation that is a variation of an optical characteristic of the projection optical system affecting imaging of a first pattern extending in a first direction under the illumination condition and second variation information indicating a second variation that is a variation of the optical characteristic of the projection optical system affecting imaging of a second pattern extending in a second direction different from the first direction under the illumination condition; a generation step of generating control data by performing weighting based on the first light intensity distribution and the second light intensity distribution and obtaining a weighted average of the first variation and the second variation; and an exposure step of performing exposure of a plurality of substrates based on the control data.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic sectional view showing the configuration of an exposure apparatus EX according to an embodiment;

FIG. 2A is a view showing the state of the exposure apparatus when measuring the angle distribution of light that enters the optical axis of the image plane of a projection optical system at the time of reticle illumination;

FIG. 2B is a view showing the state of the exposure apparatus when measuring the angle distribution of light that enters a position apart from the optical axis of the image plane of the projection optical system at the time of reticle illumination;

FIG. 3 is a schematic view showing an example of the configuration of a measurement device;

FIG. 4 is a view showing the relationship between the position of an aerial image in the optical axis direction at the time of measurement and a light amount;

FIG. 5 is a flowchart for explaining a method of predicting FocusH and FocusV that are the optical characteristics of the projection optical system;

FIG. 6 is a view exemplifying a result of predicting the generation amounts of FocusH and FocusV during execution of an exposure job;

FIG. 7 is a view exemplifying FocusH and FocusV corrected based on the aberration prediction model of FocusAve;

FIG. 8 is a view exemplifying a plurality of measurement regions of a reticle;

FIG. 9 is a view exemplifying a result of measuring a light intensity distribution formed on the pupil surface of the projection optical system by each of the plurality of measurement regions on the reticle;

FIG. 10 is a view exemplifying a light intensity distribution obtained by averaging the measurement results exemplified in FIG. 9;

FIG. 11A is a view showing the state of the exposure apparatus when measuring the angle distribution of light that enters the optical axis of the image plane of the projection optical system upon illuminating an object surface without arranging a reticle on the object surface.

FIG. 11B is a view showing the state of the exposure apparatus when measuring the angle distribution of light that enters a position apart from the optical axis of the image plane of the projection optical system upon illuminating an object surface without arranging a reticle on the object surface;

FIG. 12A is a view exemplifying a result of measuring, at a plurality of points on the image plane, light intensity distributions formed on the pupil surface of the projection optical system upon illuminating an object surface without arranging a reticle on the object surface;

FIG. 12B is a view exemplifying a light intensity distribution (b) obtained by averaging results of measuring, at a plurality of points on the image plane, light intensity distributions formed on the pupil surface of the projection optical system upon illuminating an object surface without arranging a reticle on the object surface;

FIG. 13 is a view exemplifying a first light intensity distribution (solid line) formed on the pupil surface of the projection optical system when a reticle is arranged on the object surface of the projection optical system and the reticle is illuminated, and a second light intensity distribution (dotted line) formed on the pupil surface of the projection optical system when the object surface of the projection optical system is illuminated without arranging a reticle on the object surface of the projection optical system;

FIG. 14 is a view exemplifying an exposure aberration generation amount and a fitting result;

FIG. 15 is a view exemplifying a correction result of the exposure aberration;

FIG. 16 is a view exemplifying another correction result of the exposure aberration;

FIG. 17 is a view exemplifying a first light intensity distribution (solid line) formed on the pupil surface of the projection optical system when a reticle is arranged on the object surface of the projection optical system and the reticle is illuminated, and a second light intensity distribution (dotted line) formed on the pupil surface of the projection optical system when the object surface of the projection optical system is illuminated without arranging a reticle on the object surface of the projection optical system;

FIG. 18 is a view exemplifying FocusAve, FocusH, and FocusV when wafers of one lot were exposed using the reticle that brought the result shown in FIG. 17;

FIG. 19 is a view exemplifying changes of FocusAve, FocusH, and FocusV caused by execution of calibration; and

FIG. 20 is a view exemplifying a control method according to an embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

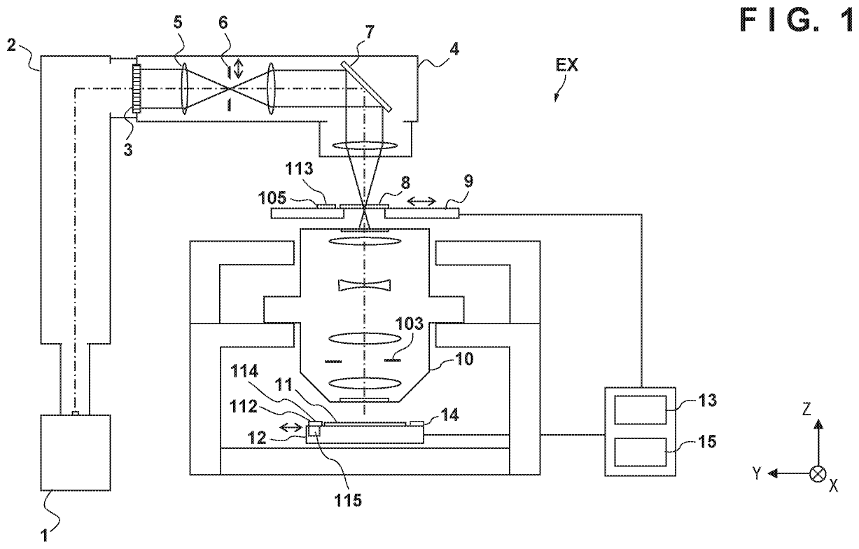

FIG. 1 is a schematic sectional view showing the configuration of an exposure apparatus EX according to an embodiment. The exposure apparatus EX is a lithography apparatus that is used in a process of manufacturing an article such as a semiconductor device and forms a pattern on a wafer (substrate). In this embodiment, the exposure apparatus EX is a step-and-scan type exposure apparatus (scanner) that exposes (scan-exposes) a wafer 11 and transfers the pattern of a reticle 8 to the wafer 11 while moving the reticle 8 and the wafer 11 in the scanning direction. However, the exposure apparatus EX can also employ the step-and-repeat method or another exposure method.

As shown in FIG. 1, the exposure apparatus EX can include a shaping optical system 2 that shapes light from a light source 1 into a predetermined shape, an illumination optical system 4 that illuminates the reticle 8 (original) with the light shaped by the shaping optical system 2, and a projection optical system 10 that projects the pattern of the reticle 8 onto the wafer 11 (substrate). The exposure apparatus EX can also include a reticle stage 9 that moves while holding the reticle 8, a wafer stage 12 that moves while holding the wafer 11, and a controller 13. The exposure apparatus EX can also include a measurement device 14 that measures the angle distribution of light that enters the surface of the wafer 11 (the image plane of the projection optical system 10), and a processing unit 15 that processes the angle distribution measured by the measurement device 14. The light source 1 includes, for example, an ArF excimer laser with a wavelength of 193 nm or a KrF excimer laser with a wavelength of 248 nm and emits light (exposure light) used to illuminate the reticle 8. The light source 1 may include an ultrahigh-pressure mercury-vapor lamp or an LED (light emitting diode). The shaping optical system 2 includes a diffraction optical element, a prism, a zoom lens unit, and an aperture stop (none are shown) inside, and shapes light from the light source 1 such that a light intensity distribution (pupil intensity distribution) having a target shape such as a circular shape, an annular shape, or a quadrupole shape is obtained on the pupil surface of the illumination optical system 4. Each of the diffraction optical element, the prism, and the aperture stop can be configured to enable selection of an arbitrary one of a plurality of candidates by a switching mechanism such as a turret. Also, the aperture stop may be an iris diaphragm whose opening diameter is changeable. The shaping optical system 2 may include an optical integrator 3, and light can exit from the optical integrator 3 toward the illumination optical system 4. The shaping optical system 2 is not limited to the above-described example, and may have another configuration.

The illumination optical system 4 is an optical system that illuminates the reticle 8 using the light than has exited from the optical integrator 3, and can include a condenser lens 5, a field stop 6, and an imaging optical system 7. The optical integrator 3 can be a wavefront splitting type optical integrator such as a fly-eye lens. The condenser lens 5 of the illumination optical system 4 includes a plurality of optical members (optical elements such as a lens and a mirror), and illuminates the field stop 6 by Koehler illumination using the light that has exited from the optical integrator 3. The exit surface of the optical integrator 3 is conjugate with the pupil surface of the illumination optical system 4, and the numerical aperture (NA) of the illumination optical system 4 can be changed by changing the size of the light intensity distribution formed on the exit surface of the optical integrator 3. The ratio (NAIL÷NAPO) of the numerical aperture (NAIL) of the illumination optical system 4 to the numerical aperture (NAPO) of the projection optical system 10 can be called a coherence factor (σ value). The σ value is an important value that decides the resolution of a pattern projected onto the wafer 11.

The configurations of the optical integrator 3 and the illumination optical system 4 are not limited to the above-described configurations. For example, the optical integrator 3 may be an internal reflection type optical integrator such as an optical rod. If the optical integrator 3 is an optical rod, the illumination optical system 4 may include an imaging optical system that forms, on the field stop 6, an image of an illuminance distribution formed on the exit surface of the optical rod in place of the condenser lens 5, that is, illuminates the field stop 6 by critical illumination. Alternatively, the field stop 6 may be arranged near the exit surface of the optical rod. The imaging optical system 7 is an optical system that includes a plurality of optical members (optical elements such as a lens and a mirror) and forms an image of the field stop 6 on the reticle 8 arranged on the target illumination surface of the illumination optical system 4 (the object surface of the projection optical system 10). The field stop 6 is arranged to define the illumination range of the reticle 8 held by the reticle stage 9 and can be scanned in synchronism with the reticle stage 9 and the wafer stage 12.

The projection optical system 10 includes a plurality of optical members (optical elements such as a lens and a mirror) and projects the pattern of the reticle 8 onto the wafer 11. The projection optical system 10 may be a refraction optical system, a reflection optical system, or a catadioptric system. The resolution of the pattern projected to the wafer 11 depends on the numerical aperture of the projection optical system 10, and the light intensity distribution (or the σ value) on the pupil surface of the projection optical system 10. An aperture stop 103 is a stop which is arranged on the pupil surface of the projection optical system 10 and whose opening diameter is changeable, and decides the numerical aperture of the projection optical system 10. The reticle 8 is arranged on the object surface of the projection optical system 10, and the wafer 11 is arranged on the image plane of the projection optical system 10. The controller 13 controls the units of the exposure apparatus EX, thereby controlling scan exposure of the wafer 11. The controller 13 can be formed by, for example, a Programmable Logic Device (PLD) such as a Field Programmable Gate Array (FPGA), an Application Specific Integrated Circuit (ASIC), a general-purpose or dedicated computer with a program installed therein, or a combination of some or all of these.

In the exposure apparatus EX, light emitted from the light source 1 in scan exposure illuminates the reticle 8 held by the reticle stage 9 via the shaping optical system 2 and the illumination optical system 4. The pattern of the reticle 8 illuminated by the illumination optical system 4 is projected by the projection optical system 10 (an image is formed) on the wafer 11 held by the wafer stage 12. The pattern of the reticle 8 can be transferred to the wafer 11 by scanning the reticle 8 and the wafer 11 at a speed ratio according to the projection magnification ratio of the projection optical system 10.

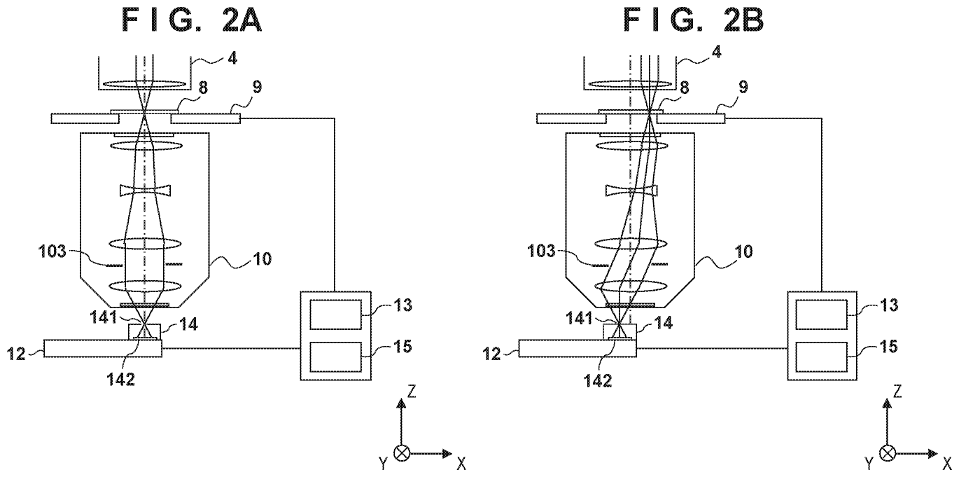

The measurement device 14 is arranged on the wafer stage 12 and measures the angle distribution of light that enters the surface of the wafer 11, that is, the image plane of the projection optical system 10. FIG. 2A shows the state of the exposure apparatus EX when measuring the angle distribution of a light beam that enters the optical axis of the image plane of the projection optical system 10. The wafer stage 12 is positioned such that a pinhole 141 of the measurement device 14 arranged on the wafer stage 12 is located on the image plane of the projection optical system 10 on the optical axis. The measurement device 14 includes a light receiving unit 142 arranged at a position apart from the pinhole 141 by a distance d in the −Z-axis direction. The light receiving unit 142 is a photoelectric conversion element such as a CCD or a CMOS, and a two-dimensional image sensor is preferably used.

The light that has entered the pinhole 141 arranged on the image plane enters a position r to the light receiving surface of the light receiving unit 142 arranged apart from the pinhole 141 by the distance d. Since r=d×tan θ, the angle distribution of the light that enters the pinhole 141 arranged on the image plane can be measured based on the position where the light enters the light receiving surface. The angle distribution depends on the light intensity distribution on the aperture stop 103 of the projection optical system 10, that is, on the pupil surface. Hence, a distribution depending on the light intensity distribution on the pupil surface of the projection optical system 10 is measured. Since the pupil surface and the image plane of the projection optical system 10 hold an orthogonal projection relationship, the light intensity distribution on the pupil surface of the projection optical system 10 can be acquired by coordinate-converting the tan θ distribution measured by the light receiving unit 142 into a sine distribution. The coordinate conversion processing is performed by the processing unit 15, thereby acquiring the light intensity distribution on the pupil surface of the projection optical system 10, that is, exit pupil light intensity distribution.

FIG. 2B shows the state of the exposure apparatus EX when measuring the angle distribution of light that enters a position apart from the optical axis of the image plane of the projection optical system 10. The wafer stage 12 is positioned such that the pinhole 141 of the measurement device 14 arranged on the wafer stage 12 is located at a position not on the optical axis of the image plane of the projection optical system 10, and the angle distribution of light that enters the image plane is measured by the measurement device 14. The exit pupil light intensity distribution at the position apart from the optical axis of the image plane of the projection optical system 10 can be acquired by coordinate-converting the measured angle distribution by the processing unit 15.

An example in which the pinhole 141 is arranged on the image plane of the projection optical system 10 has been described above. However, the present disclosure is not limited to this, and the pinhole may be arranged on the side of the reticle 8. That is, in place of the pinhole 141 formed on the measurement device 14, a pinhole pattern may be arranged on the reticle 8. Alternatively, a plate of the same material and thickness as the reticle may be arranged on the reticle stage 9, and a pinhole pattern may be arranged on the plate. If the pinhole is arranged on the side of the reticle 8 (on the side of the object surface of the projection optical system 10), the wafer stage 12 is driven such that the center or reference point of the light receiving unit is positioned at an image plane position where the angle distribution is to be measured. Also, the reticle stage 9 is driven such that the reticle-side pinhole is positioned at a position corresponding to the center or reference point of the light receiving unit on the reticle surface. Measurement can be performed in this state. The pinhole may be arranged on both the image plane side and the reticle side.

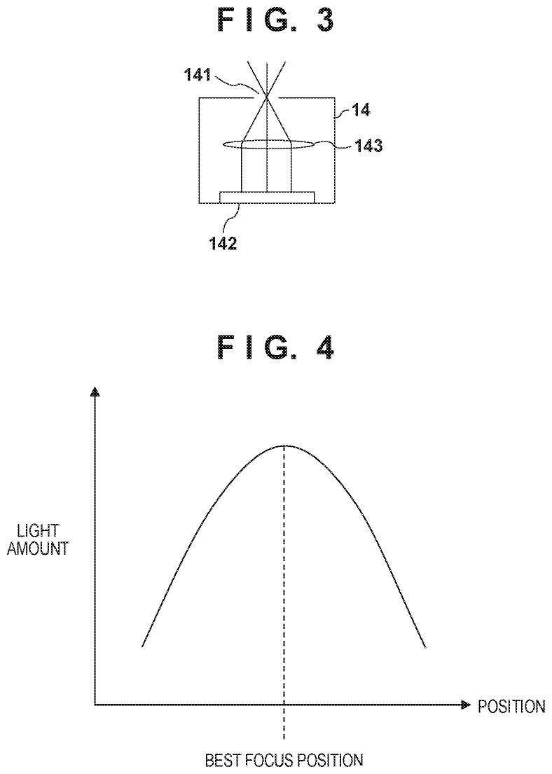

By the way, to more directly acquire the exit pupil light intensity distribution of the projection optical system 10, as shown in FIG. 3, a Fourier transformation optical system 143 may be provided in the measurement device 14. The image plane of the projection optical system 10 (or the pinhole 141) is arranged on the front focal plane of the Fourier transformation optical system 143, and the light receiving unit 142 is arranged on the rear focal plane of the Fourier transformation optical system 143. The Fourier transformation optical system 143 is an orthogonal projection optical system having a focal length f, and light reaches a position r=f×sin θ with respect to the position r of the light receiving unit 142. That is, since the light receiving unit 142 is conjugate with the pupil surface of the projection optical system 10, the exit pupil light intensity distribution of the projection optical system 10 can more directly be measured by the measurement device 14.

A method of measuring the best focus position of the projection optical system 10 will be described next. A reticle reference plate 105 different from the reticle 8 is arranged on the reticle stage 9, and a reticle-side mark 113 used to measure an aerial image can be arranged on the reticle reference plate 105. The reticle-side mark 113 can have a line-and-space pattern in which a plurality of lines are periodically arranged. Furthermore, a detection plate 112 is arranged on the wafer stage 12, and a wafer-side mark 114 used to measure an aerial image can be arranged on the detection plate 112. The wafer-side mark 114 can have a line-and-space pattern in which a plurality of lines are arranged at the same period as period×projection magnification on the reticle side. Furthermore, a photodetector 115 can be arranged under the detection plate 112. The lines of the line-and-space patterns of the reticle-side mark 113 and the wafer-side mark 114 are formed by, for example, chromium films, and the spaces can be formed by the gaps between the chromium films.

In measurement of the best focus position, first, the reticle stage 9 is positioned such that the reticle-side mark 113 on the reticle reference plate 105 is irradiated with light emitted from the light source 1 via the illumination optical system 4. Then, the reticle-side mark 113 on the reticle reference plate 105 is irradiated with the light emitted from the light source 1 via the illumination optical system 4. The light with which the line-and-space pattern of the reticle-side mark 113 is irradiated is diffracted by the line-and-space pattern and enters the projection optical system 10. The light that has entered the projection optical system 10 passes through the aperture stop 103 arranged on the pupil surface of the projection optical system 10. At this time, high-order diffracted light is blocked, and remaining 0th- and low-order diffracted light beams reach the image plane of the projection optical system 10. The light that has reached the image plane of the projection optical system 10 passes through the line-and-space pattern of the wafer-side mark 114 on the detection plate 112 arranged on the wafer stage 12 and is received by the photodetector 115. The image of the line-and-space pattern of the reticle-side mark 113 is reduced and projected in accordance with the projection magnification of the projection optical system 10 and projected to the line-and-space pattern on the wafer-side mark 114. If the wafer stage 12 is scanned and driven in the optical axis direction (Z-axis direction) in the reduction projection state, the reduction-projected image of the reticle-side mark 113 overlaps the wafer-side mark 114 at the best focus position of the projection optical system 10. Hence, the amount of light received by the photodetector 115 is maximum at the best focus position. Along with deviation from the best focus position, the contrast of the reduction-projected image of the reticle-side mark 113 lowers and the image is blurred on the wafer-side mark 114 on the detection plate 112 and, therefore, the amount of light received by the photodetector 115 gradually decreases.

FIG. 4 shows a focus curve obtained by scanning and driving the wafer stage 12 in the Z-axis direction while sandwiching the best focus position in a state in which the reticle-side mark 113 is reduced and projected onto the wafer-side mark 114. In FIG. 4, the abscissa indicates a position int the optical axis direction (Z-axis direction), and the ordinate indicates the light amount measured by the photodetector 115. The focus curve is a curve projecting upward, and a position where the curve exhibits a peak is the best focus position. The best focus position measurement method described here is merely an example, and the best focus position may be measured by another method. Note that measuring the best focus position is also called focus measurement.

To measure an astigmatism, line-and-space patterns in the X-axis direction and the Y-axis direction can be arranged on both the reticle-side mark 113 and the wafer-side mark 114. Here, the line-and-space pattern in the X-axis direction is an example of a pattern extending in the X-axis direction (first direction), and the line-and-space pattern in the Y direction is an example of a pattern extending in the Y-axis direction (second direction) different from the X-axis direction. The X-axis direction and the Y-axis direction are directions orthogonal to each other. In a state in which the line-and-space patterns of the reticle-side mark 113 in the X-axis and Y-axis directions are reduced and projected onto the wafer-side mark 114, the wafer stage 12 is scanned and driven in the Z-axis direction through the range in which both the line-and-space patterns in the X-axis and Y-axis directions include the best focus position. The focus curves of the line-and-space patterns in the X-axis and Y-axis directions are thus obtained. The controller 13 calculates best focus positions at which the acquired focus curves of the line-and-space patterns in the X-axis and Y-axis directions exhibit a peak. The best focus of the line-and-space pattern in the X-axis direction will be expressed as FocusV, and the best focus position of the line-and-space pattern in the Y-axis direction will be expressed as FocusH. The controller 13 may also obtain the difference between FocusH and FocusV as an astigmatism. The average of FocusH and FocusV will be expressed as FocusAve.

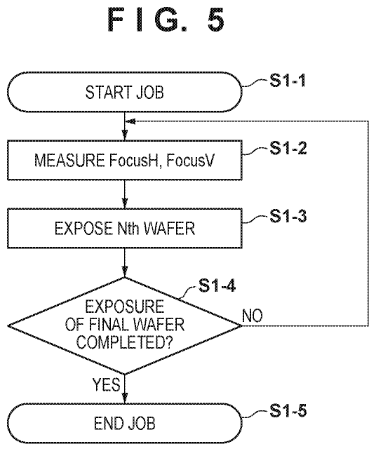

A method of predicting FocusH and FocusV that are the optical characteristics of the projection optical system 10 will be described below with reference to FIG. 5. In step S1-1, the controller 13 starts an exposure job and conveys the reticle 8 to the reticle stage 9. Also, in step S1-1, the controller 13 conveys the wafer 11 to the wafer stage 12. Next, in step S1-2, before the start of exposure of the wafer 11, the controller 13 measures FocusH and FocusV under an illumination condition (illumination mode) for exposure. Here, the illumination condition means the effective light source distribution (in other words, the light intensity distribution on the pupil surface of the illumination optical system 4). In step S1-3, the controller 13 executes exposure of the Nth wafer 11 of a lot. In step S1-4, the controller 13 determines whether exposure of the final wafer 11 of the lot is completed. Upon determining that exposure of the final wafer 11 is completed, the job is ended in step S1-5. Otherwise, steps S1-2 and S1-3 are repeated.

When fitting of aberration prediction models represented by equations (1), (2), and (3) is performed using FocusH and FocusV measured by the above-described method, variations of FocusH and FocusV during execution of the exposure job can be predicted. Note that fitting a model and generating a model mean deciding the parameter values of a model by fitting. Φ is a predicted generation amount of modeled FocusH, and N in a suffix indicates the measured timing of FocusH. In this specification, prediction model parameters Pₘ (m=1, 2, 3) including three time constants Kₘ (m=1, 2, 3) are used. The prediction model parameter Pₘ indicates the saturation amount of FocusH. m indicates a model number and, in this specification, m=1 is a long-term time constant model, m=2 is a medium-term time constant model, and m=3 is a short-term time constant model. α indicates an exposure load which takes a different value depending on the exposure condition. The exposure load α is represented by a function of a transmittance R of the reticle, an exposure amount D, a shot region size A, the number Num of shot regions to be exposed between measurement of FocusH and next measurement of FocusH, and a time T during this. Other parameters such as the reflectance of the resist may be used in the calculation of the exposure load. A variable at the time of fitting is a prediction model parameter which is a value unique to the job. For FocusV as well, fitting of the same exposure aberration model as that for FocusH is performed.

Also, FocusAve is predicted in advance using the aberration prediction models represented by equations (1), (2), and (3), and FocusAve during execution of the exposure job is corrected by driving the wafer stage 12 in the Z-axis direction. As for the measurement values of FocusH and FocusV, since a correction residue from FocusAve is measured, the generation amounts of FocusH and FocusV can be calculated based on the measurement values of FocusH and FocusV and the correction amount of FocusAve.

$${∅}_{N} = {∅}_{1 N} + {∅}_{2 N} + {∅}_{3 N} \qquad ( 1 )$$

$${∅}_{mN} = {P}_{m} * {α}_{N} - ( {P}_{m} * {α}_{N} - {∅}_{mN - 1} ) * exp ( - \frac{{T}_{N}}{{K}_{m}} ) \qquad ( 2 )$$

$${α}_{N} = \frac{R * D * A * {Num}_{N}}{{T}_{N}} \qquad ( 3 )$$

Here, for FocusH, let P₁ₕ, P₂ₕ, and P₃ₕ be the prediction model parameters Pm (m=1, 2, 3) decided by fitting. Also, for FocusV, let P₁ᵥ, P₂ᵥ, and P₃ᵥ be the prediction model parameters Pm (m=1, 2, 3) decided by fitting.

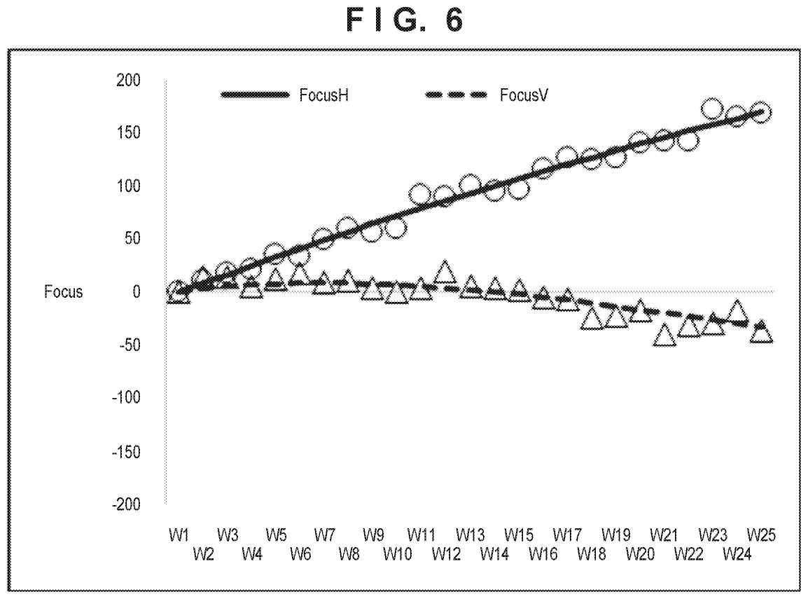

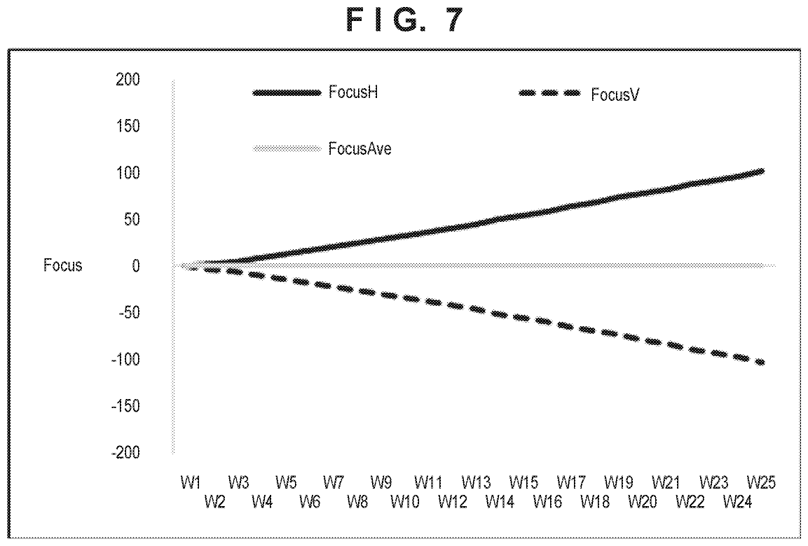

FIG. 6 shows an example of a result of predicting the generation amounts of FocusH and FocusV during execution of an exposure job. In FIG. 6, the abscissa indicates a wafer number, and the ordinate indicates the generation amounts of FocusH and FocusV. A circle indicates a variation of the generation amount of FocusH, and a triangle indicates a variation of the generation amount of FocusV. In FIG. 6, a solid line and a dotted line respectively indicate FocusH and FocusV predicted using the exposure aberration prediction models. The controller 13 can generate the aberration prediction models based on the measurement values obtained at the time of execution of the exposure job, and when executing an exposure job of the same condition as the exposure job, predict the generation amounts of FocusH, FocusV, and FocusAve using the aberration prediction models. The predicted FocusAve can be corrected by driving the wafer stage 12. FIG. 7 exemplifies FocusH and FocusV corrected based on the aberration prediction model of FocusAve.

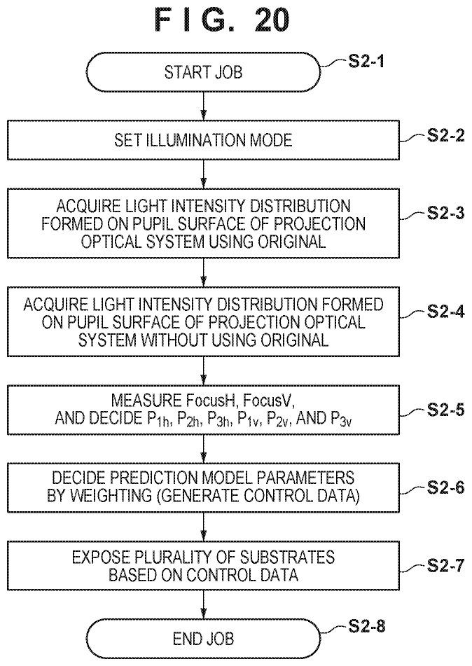

A control method of the exposure apparatus EX according to this embodiment or an exposure method in the exposure apparatus EX will be described below with reference to FIG. 20. Processing shown in FIG. 20 is controlled by the controller 13. The controller 13 can also be understood as a control apparatus that controls the exposure apparatus EX. The controller 13 may be formed by installing a program in a computer.

In step S2-1, the controller 13 starts an exposure job and conveys the reticle 8 to the reticle stage 9. Also, in step S2-1, the controller 13 conveys the wafer 11 to the wafer stage 12. In step S2-2, the controller 13 sets an illumination condition (that is, an illumination condition for exposure) designated by the exposure job. Setting of the illumination condition can be done by controlling the shaping optical system 2. The set illumination condition is maintained at least until the exposure job is ended.

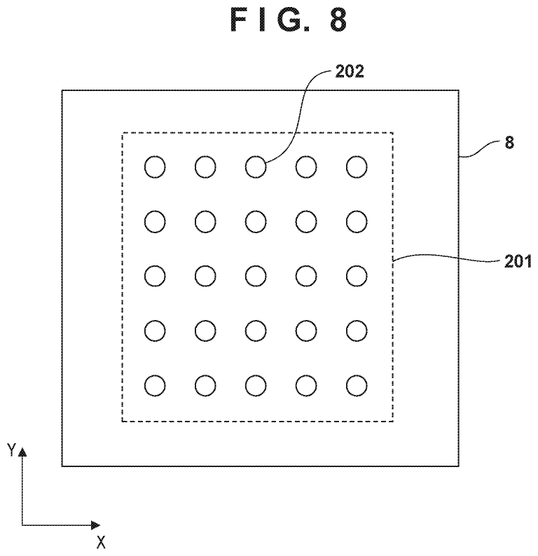

In step S2-3, the controller 13 acquires a first light intensity distribution formed on the pupil surface of the projection optical system 10 when the reticle 8 is illuminated under the set illumination condition. The first light intensity distribution formed on the pupil surface of the projection optical system 10 can be acquired in accordance with the method described with reference to FIG. 2. Here, the aberration of the projection optical system 10 caused by the exposure is affected not by a part of the exposure region of the reticle 8 but by the entire pattern region of the reticle 8. It is therefore preferable to consider the entire pattern region of the reticle 8 when acquiring the first light intensity distribution. For this reason, as shown in FIG. 8, it is preferable to measure the light intensity distribution formed on the pupil surface of the projection optical system 10 by diffracted light from each of, for example, 25 measurement regions 202 such that these represent an entire exposure region 201 of the reticle 8. Concerning the Y-axis direction (scanning direction), selection of the measurement regions 202 can be performed by moving the reticle stage 9. Concerning the X-axis direction (a direction orthogonal to the scanning direction), selection of the measurement regions 202 can be performed by moving the wafer stage 12 to each of the five points.

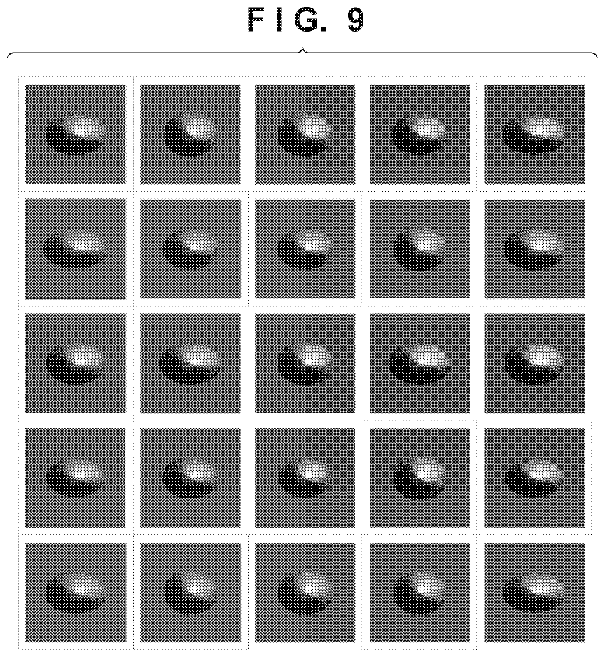

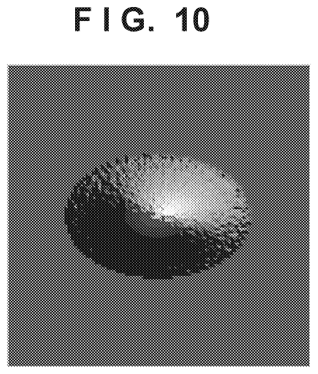

FIG. 9 exemplifies, for each of the 25 measurement regions 202 on the reticle, a result of measuring the first light intensity distribution formed on the pupil surface of the projection optical system 10 by the diffracted light the measurement region 202. Note that the number of measurement regions 202 on the reticle 8 is not limited to 25 and can be an arbitrary number. As exemplified in FIG. 10, the controller 13 averages the first light intensity distributions formed by the diffracted light beams from the 25 measurement regions 202, thereby generating an average light intensity distribution.

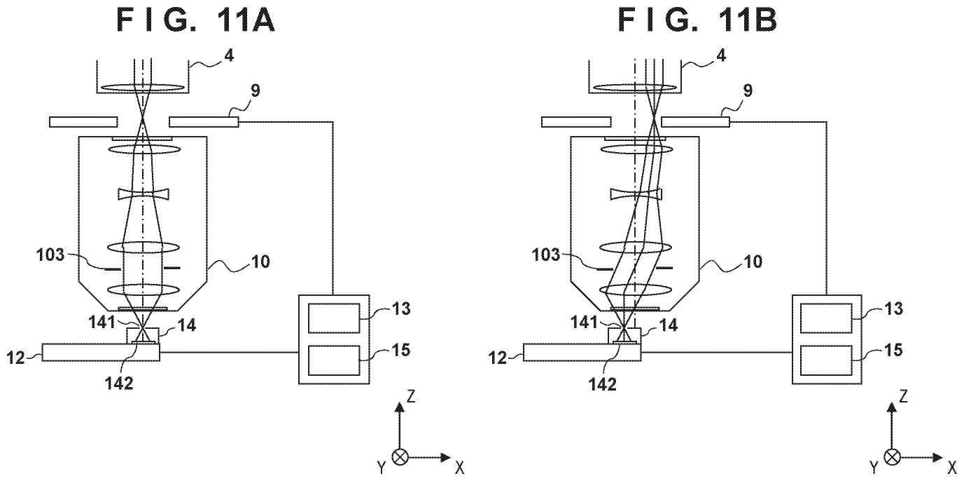

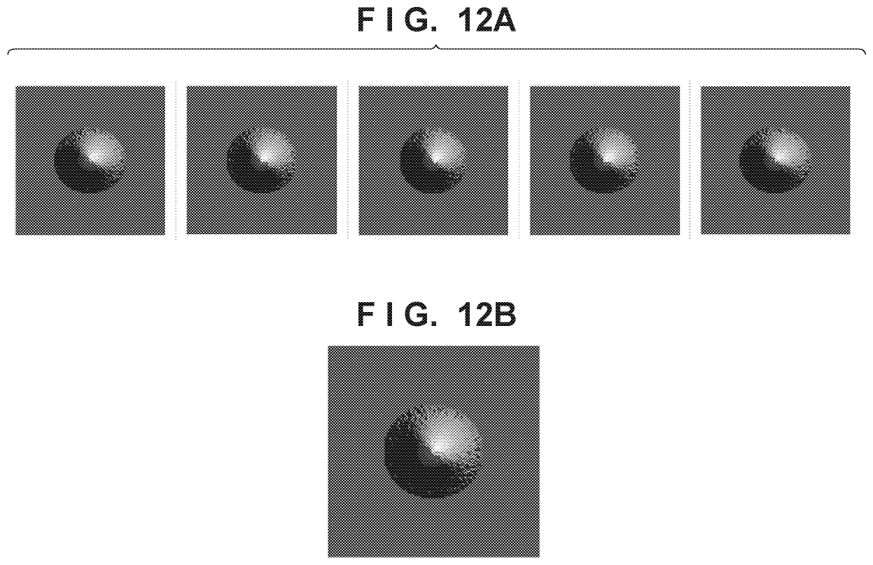

In step S2-4, the controller 13 acquires a second light intensity distribution formed on the pupil surface of the projection optical system 10 when the object surface of the projection optical system 10 is illuminated under the set illumination condition without using the reticle 8, as shown in FIGS. 11A and 11B. The second light intensity distribution formed on the pupil surface of the projection optical system 10 can also be acquired in accordance with the method described with reference to FIG. 2. In a case where the reticle 8 is not used, even if the reticle stage 9 is moved in the Y-axis direction, the second light intensity distribution formed on the pupil surface of the projection optical system 10 does not change. Hence, in step S2-4, the controller 13 acquires the second light intensity distribution for each of five points in the X-axis direction (the same positions as the positions on the wafer stage 12 when five measurement regions 202 arranged in the X-axis direction of the reticle 8 are the measurement targets). FIG. 12A exemplifies a result of measuring, at a plurality of points on the image plane, the second light intensity distributions formed on the pupil surface of the projection optical system 10 upon illuminating the object surface without arranging the reticle 8 on the object surface. As exemplified in FIG. 12B, the controller 13 averages the five second light intensity distributions shown in FIG. 12A, thereby generating an average light intensity distribution.

Steps S2-3 and S2-4 correspond to a first acquisition step of acquiring the first light intensity distribution formed on the pupil surface of the projection optical system 10 under the illumination condition set using the reticle 8 and the second light intensity distribution formed on the pupil surface of the projection optical system 10 under the illumination condition set without using the reticle 8.

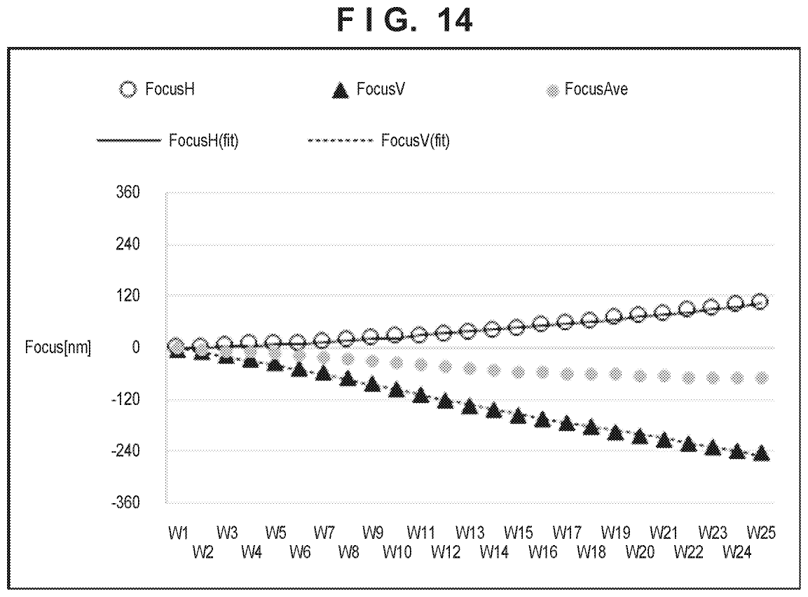

In step S2-5, the controller 13 measures FocusH and Focus V in accordance with the method described with reference to FIG. 5 and decides P₁ₕ, P₂ₕ, P₃ₕ, P₁ᵥ, P₂ᵥ, and P₃ᵥ. That is, the controller 13 measures FocusH using the pattern extending in the X-axis direction (first direction) (the line-and-space pattern in the X-axis direction) and performs fitting of the prediction model to the result, thereby deciding the prediction model parameters P₁ₕ, P₂ₕ, and P₃ₕ. In addition, the controller 13 measures FocusV using the pattern extending in the Y-axis direction (second direction) (the line-and-space pattern in the Y-axis direction) and performs fitting of the prediction model to the result, thereby deciding the prediction model parameters P₁ᵥ, P₂ᵥ, and P₃ᵥ. FIG. 14 exemplifies the result. In an example, P₁ₕ=239.9, P₂ₕ=−203.3, P₃ₕ=721.7, P₁ᵥ=−177.2, P₂ᵥ=13.3, and P₃ᵥ=−780.2. The prediction model of FocusH decided by the prediction model parameters P₁ₕ, P₂ₕ, and P₃ₕ is first variation information indicating a first variation that is a variation of the optical characteristic of the projection optical system 10 affecting imaging of the pattern extending in the X-axis direction (first direction). The prediction model of FocusV decided by the prediction model parameters P₁ᵥ, P₂ᵥ, and P₃ᵥ is an example of second variation information indicating a second variation that is a variation of the optical characteristic of the projection optical system 10 affecting imaging of the pattern extending in the Y-axis direction (second direction). Step S2-5 is a second acquisition step of acquiring the first variation information and the second variation information.

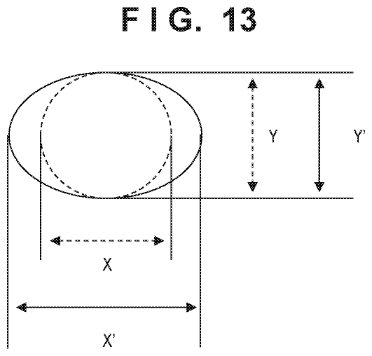

In step S2-6, the controller 13 obtains the weighted average of the first variation and the second variation by performing weighting based on the first light intensity distribution and the second light intensity distribution, thereby generating control data for reducing the influence by the variation of the optical characteristic of the projection optical system 10. First, a method of performing weighting based on the first light intensity distribution and the second light intensity distribution will exemplarily be described. In FIG. 13, an example of the first light intensity distribution formed on the pupil surface of the projection optical system 10 when the reticle 8 is illuminated under an illumination condition set while arranging the reticle 8 on the object surface of the projection optical system 10 is indicated by a solid line. Also, in FIG. 13, an example of the second light intensity distribution formed on the pupil surface of the projection optical system 10 when the object surface of the projection optical system 10 is illuminated under an illumination condition set without arranging the reticle 8 on the object surface of the projection optical system 10 is indicated by a dotted line.

The X-axis direction size (maximum size) of the second light intensity distribution (without the reticle 8) indicated by the dotted line is X, and the X-axis direction size (maximum size) of the first light intensity distribution (with the reticle) indicated by the solid line is X′. In addition, the Y-axis direction size (maximum size) of the second light intensity distribution (without the reticle) indicated by the dotted line is Y, and the Y-axis direction size (maximum size) of the first light intensity distribution (with the reticle 8) indicated by the solid line is Y′. Here, RX=X′/X and RY=Y′/Y are defined as ratios.

In the example shown in FIG. 13, ratio RX=1.4, and ratio RY=1.0. That the ratio RY is 1.0 means that the first light intensity distribution formed using the reticle 8 and the second light intensity distribution (without the reticle) formed without using the reticle 8 are the same. In other words, that the ratio RY is 1.0 means that there is no diffracted light that exits from the pattern of the reticle 8 in the Y-axis direction. Hence, that the ratio RY is 1.0 indicates that the line width of the pattern (to the referred to as an H pattern hereinafter) that is arranged on the reticle 8 to extend in the X-axis direction (horizontal direction) is thick. Also, that the ratio RX is 1.4 means that the light intensity distribution formed on the pupil surface of the projection optical system 10 extends in the X-axis direction in a case where the reticle 8 is used more than in a case where the reticle 8 is not used. In other words, that the ratio RX is 1.4 means that there is certain diffracted light that exits from the pattern of the reticle 8 in the X-axis direction (horizontal direction). Hence, that the ratio RX is 1.4 indicates that the line width of the pattern (to the referred to as a V pattern hereinafter) that is arranged on the reticle 8 to extend in the Y-axis direction (vertical direction) is thin.

Here, if the line width of the pattern is thick, the line width of the pattern projected to the image plane is insensitive to a variation of the focus position. Even if the focus position deviates, degradation of the contrast of the pattern projected to the image plane is small, and the change of the size of the line width of the transferred pattern is small. To the contrary, if the line width of the pattern is thin, the line width of the pattern projected to the image plane is sensitive to a variation of the focus position. If the focus position deviates, degradation of the contrast of the pattern projected to the image plane is large, and the change of the size of the line width of the transferred pattern is large. Hence, the focus position is preferably set based on FocusV that affects the V pattern sensitive to the focus position rather than FocusH that affects the H pattern insensitive to the focus position.

Next, to cancel the influence of the second light intensity distribution formed on the pupil surface of the projection optical system 10 without using the reticle 8, the controller 13 subtracts 1.0 from RX and RY, thereby obtaining RX1=0.4 and RY1=0.0. Furthermore, the controller 13 calculates the integer ratio of RX1:RX2, thereby obtaining RX2:RY2=1:0. RX2:RY2 indicates weighing of FocusV and FocusH. RY2=0 means that weighting of FocusH is 0, that is, FocusH is not corrected at all. On the other hand, RX2=1 means that weighting of FocusV is 1.

Note that if RX=1.8 and RY=1.2, RX1=0.8, RY1=0.2, and RX2:RY2=4:1. In this case, the weighting of FocusV is 4, and the weighting of FocusH is 1. This means that the focus position is corrected such that the correction residues upon correcting the focus position are 1 for FocusV and 4 for FocusH.

Also, if RX=1.0 and RY=1.0, RX1=0.0, RY1=0.0, and RX2:RY2=1:1. This means that the focus position is corrected such that the correction residue of Focus V and that of FocusH equal.

Calculation of prediction model parameters of an exposure aberration will be described below using a case where weighting RX2:RY2=1:0 as an example. Assume that in step S2-5, the prediction model parameters are decided to P₁ₕ=239.9, P₂ₕ=−203.3, P₃ₕ=721.7, P₁ᵥ=−177.2, P₂ᵥ=13.3, and P₃ᵥ=−780.2, as described above.

Using the weighting RX2:RY2, the controller 13 can decide prediction model parameters P_{1A}, P_{2A}, and P_{3A} of FocusAve in accordance with equations (4), (5), and (6).

P_{1A}=P₁ₕ×RY2/(RX2+RY2)+P₁ᵥ×RX2/(RX2+RY2) (4)

P_{2A}=P₂ₕ×RY2/(RX2+RY2)+P₂ᵥ×RX2/(RX2+RY2) (5)

P_{3A}=P₃ₕ×RY2/(RX2+RY2)+P₃ᵥ×RX2/(RX2+RY2) (6)

FocusAve in which the prediction model parameters P_{1A}, P_{2A}, and P_{3A} are expressed by equations (4), (5), and (6) is control data for controlling the position of the wafer stage 12 in the Z-axis direction (the optical axis direction of the projection optical system 10). The control data is control data generated to reduce the influence of the variation of the average of the best focus position of a first pattern extending in the X-axis direction and the best focus position of a second pattern extending in the Y-axis direction.

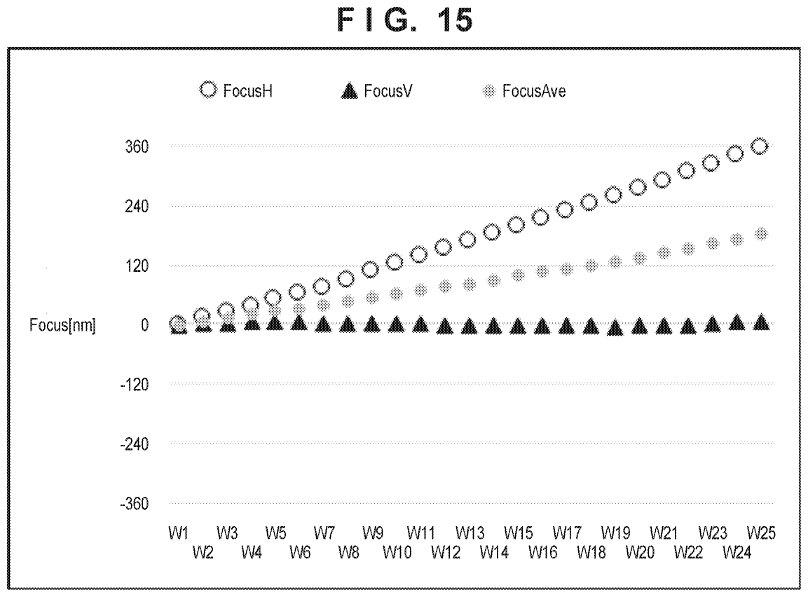

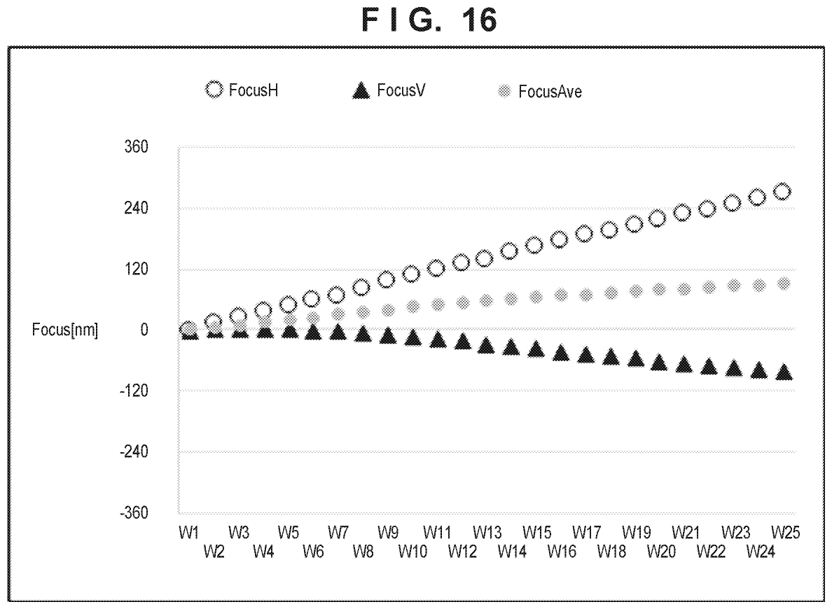

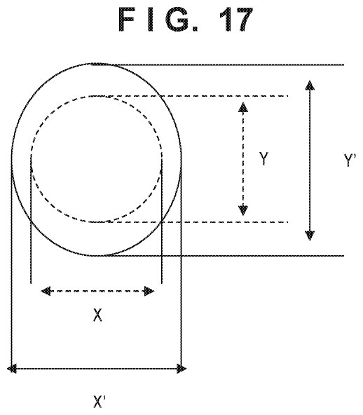

Since RX2:RY2=1:0, P_{1A}=−177.2, P_{2A}=13.3, and P_{3A}=−780.2. FIG. 15 shows a result of correcting the focus position in accordance with the prediction model parameters. It is found that FocusV is corrected not to vary along with the elapse of time. For example, if RX2:RY2=4:1, P_{1A}=−83, P_{2A}=30.0, and P_{3A}=−479.8. FIG. 16 shows a result of correcting the focus position in accordance with the prediction model parameters. In FIG. 15, FocusV does not vary along with the elapse of time, but in FIG. 16, FocusV varies along with the elapse of time. However, the variation of FocusH along with the elapse of time is smaller in FIG. 16 than in FIG. 15.

In step S2-7, the controller 13 executes an exposure step. More specifically, the controller 13 performs exposure of a plurality of wafers constituting a lot while controlling the position of the wafer stage 12 in the Z-axis direction (the optical axis direction of the projection optical system 10) based on the control data. In the exposure step, the controller 13 performs focus control with focus measurement for a wafer to be exposed first in the plurality of wafers constituting the lot, and does not perform focus control with focus measurement for at least one substrate among the remaining substrates. After that, in step S2-8, the controller 13 ends the exposure job.

As described above, the control data is generated by obtaining the weighted average of the first variation and the second variation while performing weighting based on the first light intensity distribution and the second light intensity distribution, thereby easily reducing the correction residue of the exposure aberration.

In the above-described embodiment, saturation values that are the prediction model parameters are obtained by weighting based on the ratio of the first direction (X-axis direction) size to the second direction (Y-axis direction) size of the light intensity distribution on the pupil surface of the projection optical system 10. This is merely an example, and the weighting may be performed in accordance with another method.

In the above embodiment, an example in which FocusH and FocusV are corrected by FocusAve has been described, but this is merely an example. For example, FocusH may be replaced with a magnification that varies in the X-axis direction in accordance with a linear function, FocusV may be replaced with a magnification that varies in the Y-axis direction in accordance with a linear function, and FocusAve may be replaced with a magnification that changes isotropically in the X-axis and Y-axis directions. In this case, the magnification of the projection optical system 10 can be corrected by driving optical elements (lenses and mirrors) in the projection optical system 10.

As another embodiment, an example in which focus calibration is performed based on the measurement result of a light intensity distribution formed on the pupil of the projection optical system 10 by diffracted light from the pattern of the reticle 8 will be described below. Here, the description will be made with reference to FIG. 17 which shows an example of the first light intensity distribution formed on the pupil surface of the projection optical system 10 using the reticle 8 and the second light intensity distribution formed on the pupil surface of the projection optical system 10 without using the reticle 8. Note that in FIG. 17, the first light intensity distribution formed on the pupil surface of the projection optical system 10 using the reticle 8 is indicated by a solid line, and the second light intensity distribution formed on the pupil surface of the projection optical system 10 without using the reticle 8 is indicated by a dotted line. In the example shown in FIG. 17, RX=1.25 and RY=1.5. In this case, RX1:RY1=0.25:0.5 and RX2:RY2=1:2. This means that both the H pattern and the V pattern generate diffracted light and that the influence of the H pattern on the variation of the focus position is larger than the influence of the V pattern on the variation of the focus position. In this case, the focus position is preferably decided by giving a larger weight to FocusH affected by the H pattern sensitive to the focus position than FocusV affected by the V pattern insensitive to the focus position.

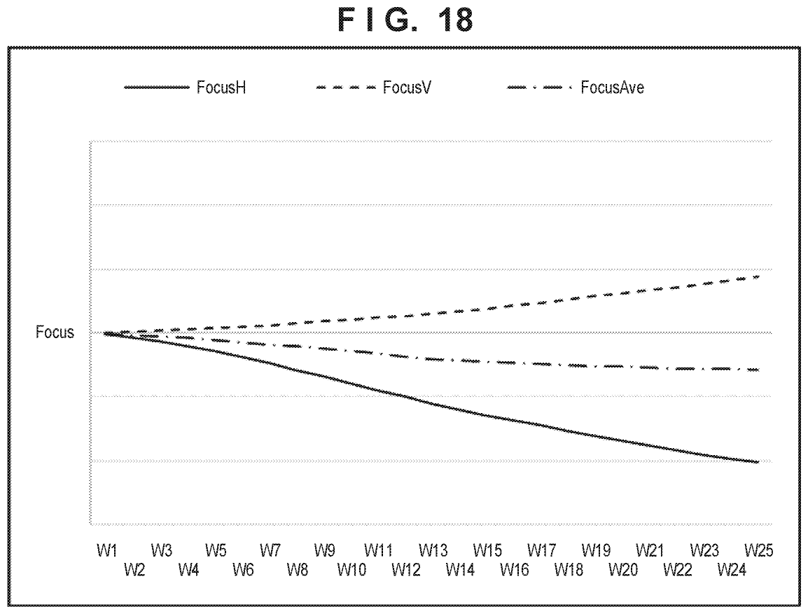

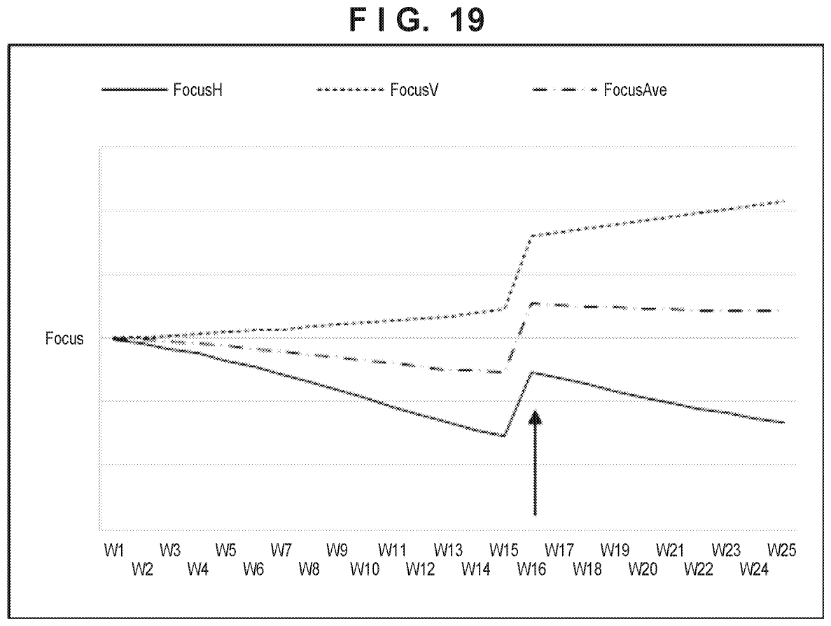

FIG. 18 shows FocusAve, FocusH, and FocusV when wafers of one lot were exposed using the reticle that brought the result shown in FIG. 17. The abscissa indicates the number of wafers, and the ordinate indicates FocusAve, FocusH, and FocusV. FIG. 19 shows a state in which calibration is performed before exposure of the 16th wafer (W16). Before exposure of the 16th wafer 11 (W16), focus measurement is executed using the above-described aerial image. If this results in FocusAve=−57.0, FocusH=−168.4, and FocusV=50.8, a correction value FocusAveComp used to correct FocusAve is given by equation (7), and FocusAveComp=−110.9. When the wafer stage 12 is driven in the Z-axis direction in accordance with FocusAveComp=−110.9, FocusH and FocusV can be corrected well in balance.

FocusAveComp=FocusH×RY2/(RX2+RY2)+FocusV×RX2/(RX2+RY2) (7)

Also, in the other embodiment, an example in which FocusH and FocusV are corrected by FocusAve has been described, but this is merely an example. For example, FocusH may be replaced with a magnification that varies in the X-axis direction in accordance with a linear function, FocusV may be replaced with a magnification that varies in the Y-axis direction in accordance with a linear function, and FocusAve may be replaced with a magnification that changes isotropically in the X-axis and Y-axis directions. In this case, the magnification of the projection optical system 10 can be corrected by driving optical elements (lenses and mirrors) in the projection optical system 10.

The exposure apparatus EX is applied to an article manufacturing method for manufacturing an article. The article manufacturing method can include a forming step of forming a pattern on a substrate by the exposure apparatus EX, and a processing step of processing the substrate that has undergone the forming step, thereby obtaining an article. The pattern formed in the forming step is, for example, a latent image formed on a photosensitive material on the substrate. The processing step can include, for example, a development step. The processing step can also include a deposition step, an etching step, a dicing step, a sealing step, and the like. In the article manufacturing method, the forming step of forming the pattern on the substrate and associated processes (for example, the development step) can be executed a plurality of times.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-067037, filed Apr. 15, 2025, which is hereby incorporated by reference herein in its entirety.

What is claimed is:

1. A control method of an exposure apparatus configured to expose a substrate by projecting, by a projection optical system, a pattern of an original to the substrate under a set illumination condition, comprising:
a first acquisition step of acquiring a first light intensity distribution formed on a pupil surface of the projection optical system when the original is arranged on an object surface of the projection optical system and the original is illuminated under the illumination condition and a second light intensity distribution formed on the pupil surface when the object surface is illuminated under the illumination condition without arranging the original on the object surface;
a second acquisition step of acquiring first variation information indicating a first variation that is a variation of an optical characteristic of the projection optical system affecting imaging of a first pattern extending in a first direction under the illumination condition and second variation information indicating a second variation that is a variation of the optical characteristic of the projection optical system affecting imaging of a second pattern extending in a second direction different from the first direction under the illumination condition;
a generation step of generating control data by performing weighting based on the first light intensity distribution and the second light intensity distribution and obtaining a weighted average of the first variation and the second variation; and
an exposure step of performing exposure of a plurality of substrates based on the control data.

2. The method according to claim 1, wherein
in the second acquisition step, a first prediction model indicating the first variation is generated as the first variation information, and a second prediction model indicating the second variation is generated as the second variation information.

3. The method according to claim 2, wherein
generating the first prediction model includes deciding a saturation value of the optical characteristic of the projection optical system concerning the first variation, and generating the second prediction model includes deciding the saturation value of the optical characteristic of the projection optical system concerning the second variation.

4. The method according to claim 1, wherein
in the second acquisition step, the first variation information is generated by measuring an image of the first pattern, and the second variation information is generated by measuring the image of the first pattern.

5. The method according to claim 1, wherein
the first variation is a variation of a best focus position of the first pattern, and the second variation is a variation of a best focus position of the second pattern.

6. The method according to claim 5, wherein
the control data includes data for focus control.

7. The method according to claim 5, wherein
the control data includes data for controlling a position of the substrate concerning an optical axis direction of the projection optical system such that focus control is performed.

8. The method according to claim 5, wherein
in the generation step, the control data is generated to reduce an influence of a variation of an average of the best focus position of the first pattern and the best focus position of the second pattern.

9. The method according to claim 5, wherein
in the exposure step, focus control with focus measurement is performed for a substrate to be exposed first in the plurality of substrates, and focus control with focus measurement is not performed for at least one substrate among remaining substrates.

10. The method according to claim 1, wherein
the first variation is a variation of a magnification of the projection optical system concerning the first direction, and the second variation is a variation of the magnification of the projection optical system concerning the second direction.

11. The method according to claim 10, wherein
the control data includes data for controlling the magnification of the projection optical system concerning the first direction and the second direction.

12. The method according to claim 1, wherein
the weighting is performed based on a size ratio of the first light intensity distribution and the second light intensity distribution concerning the first direction and a size ratio of the first light intensity distribution and the second light intensity distribution concerning the second direction.

13. A non-transitory computer-readable storage medium storing a program configured to cause a computer to execute a control method defined in claim 1.

14. A computer incorporating a program defined in claim 13 and configured as a control apparatus for controlling an exposure apparatus.

15. An exposure apparatus configured to expose a substrate by projecting, by a projection optical system, a pattern of an original to the substrate under a set illumination condition, comprising:
a measurement device configured to acquire a first light intensity distribution formed on a pupil surface of the projection optical system when the original is arranged on an object surface of the projection optical system and the original is illuminated under the illumination condition and a second light intensity distribution formed on the pupil surface when the object surface is illuminated under the illumination condition without arranging the original on the object surface; and
a controller configured to acquire first variation information indicating a first variation that is a variation of an optical characteristic of the projection optical system affecting imaging of a first pattern extending in a first direction under the illumination condition and second variation information indicating a second variation that is a variation of the optical characteristic of the projection optical system affecting imaging of a second pattern extending in a second direction different from the first direction under the illumination condition, and generate control data by obtaining a weighted average of the first variation and the second variation while performing weighting based on the first light intensity distribution and the second light intensity distribution,
wherein the controller controls exposure of a plurality of substrates based on the control data.

16. The apparatus according to claim 15, wherein
the first variation is a variation of a best focus position of the first pattern, and the second variation is a variation of a best focus position of the second pattern.

17. The apparatus according to claim 16, wherein
the control data includes data for focus control.

18. The apparatus according to claim 15, wherein
the controller generates the control data to reduce an influence of a variation of an average of the best focus position of the first pattern and the best focus position of the second pattern.

19. The apparatus according to claim 15, wherein
the controller performs focus control with focus measurement for a substrate to be exposed first in the plurality of substrates, and does not perform focus control with focus measurement for at least one substrate among remaining substrates.

20. An article manufacturing method comprising:
an exposure step of exposing a substrate by an exposure apparatus defined in claim 15; and
a processing step of processing the substrate that has undergone the exposure step, thereby obtaining an article.
